(19) United States
(12) Patent Application Publication
(10) Pub. No.: US 2024/0268136 A1
(43) Pub. Date: Aug. 8, 2024

(54) QUANTUM DOT LIGHT-EMITTING DEVICE AND METHOD FOR PATTERNING QUANTUM DOT LAYER

(71) Applicants: Beijing BOE Technology Development Co., Ltd., Beijing (CN); BOE Technology Group Co., Ltd., Beijing (CN)

(72) Inventor: Tieshi WANG, Beijing (CN)

(21) Appl. No.: 18/021,738

(22) PCT Filed: Mar. 24, 2022
(86) PCT No.: PCT/CN2022/082776

§ 371 Date: Feb. 16, 2023

(51) Int. Cl. H10K 50/115; C09K 11/06; H10K 50/15; H10K 50/16; H10K 71/20; H10K 85/60

(52) U.S. Cl. CPC H10K 50/115; C09K 11/06; H10K 50/15; H10K 50/16; H10K 71/233; H10K 85/60

(57) ABSTRACT

A quantum dot light-emitting device and a method for patterning a quantum dot layer are disclosed. The quantum dot light-emitting device includes: a substrate; and a quantum dot layer located on the substrate; where the quantum dot layer includes a first quantum dot unit, a second quantum dot unit and a third quantum dot unit that emit light of different colors; an azobenzene compound layer is arranged between the substrate and the first quantum dot unit, between the first quantum dot unit and the second quantum dot unit, and between the second quantum dot unit and the third quantum dot unit, an orthographic projection of the azobenzene compound layer on the substrate completely covers the substrate, and an azobenzene compound of the azobenzene compound layer has a trans structure.

This application is a National Stage of International Application No. PCT/CN2022/082776, filed on Mar. 24, 2022, which is hereby incorporated by reference in its entirety.

### FIELD

The disclosure relates to the field of display technology, and particularly to a quantum dot light-emitting device and a method for patterning a quantum dot layer.

### BACKGROUND

The Quantum Dot (QD), also known as semiconductor nanocrystal or semiconductor nanoparticle, has the size on the order of nanometers in three dimensions of space, or the nano-solid material composed of QDs as basic units is a collection of atoms and molecules on the nanometer scale. A light-emitting diode based on a quantum dot material is called Quantum dot Light-Emitting Diode (QLED), and is a new type of light-emitting device.

### SUMMARY

Embodiments of the disclosure provide a quantum dot light-emitting device and a method for patterning a quantum dot layer. Specific solutions are as follows.

A quantum dot light-emitting device according to an embodiment of the disclosure includes: a substrate; a quantum dot layer located on the substrate; where the quantum dot layer includes a first quantum dot unit, a second quantum dot unit and a third quantum dot unit that emit light of different colors, orthographic projections of the first quantum dot unit, the second quantum dot unit and the third quantum dot unit on the substrate do not overlap with each other, and a distance between a bottom surface of the first quantum dot unit and a surface of the substrate, a distance between a bottom surface of the second quantum dot unit and the surface of the substrate, and a distance between a bottom surface of the third quantum dot unit and the surface of the substrate increase sequentially; where: an azobenzene compound layer is arranged between the substrate and the first quantum dot unit, between the first quantum dot unit and the second quantum dot unit, and between the second quantum dot unit and the third quantum dot unit, an orthographic projection of the azobenzene compound layer on the substrate completely covers the substrate, and an azobenzene compound of the azobenzene compound layer has a trans structure.

Optionally, in the above-mentioned quantum dot light-emitting device according to an embodiment of the disclosure, a thickness of each azobenzene compound layer is in a range of 1 nm to 10 nm.

Optionally, in the above-mentioned quantum dot light-emitting device according to an embodiment of the disclosure, a surface of the third quantum dot unit is flush with a surface of the azobenzene compound layer farthest from the substrate.

Optionally, in the above-mentioned quantum dot light-emitting device according to an embodiment of the disclosure, the quantum dot layer is a film layer after ligands on surfaces of quantum dots are cross-linked.

Optionally, in the above-mentioned quantum dot light-emitting device according to an embodiment of the disclosure, the azobenzene compound layer between the substrate and the first quantum dot unit is a first azobenzene compound layer, and the quantum dot light-emitting device further includes: a first electrode located between the substrate and the first azobenzene compound layer, a first luminescent functional layer located between the first electrode and the first azobenzene compound layer, a second luminescent functional layer located on a side of the quantum dot layer away from the substrate, and a second electrode located on a side of the second luminescent functional layer away from the substrate.

Optionally, in the above-mentioned quantum dot light-emitting device according to an embodiment of the disclosure, the first electrode is an anode, the second electrode is a cathode, the first luminescent functional layer includes at least one of a hole injection layer, a hole transport layer or an electron blocking layer, and the second luminescent functional layer includes at least one of an electron injection layer, an electron transport layer or a hole blocking layer.

Optionally, in the above-mentioned quantum dot light-emitting device according to an embodiment of the disclosure, the first electrode is a cathode, the second electrode is an anode, the first luminescent functional layer includes at least one of an electron injection layer, an electron transport layer or a hole blocking layer, and the second luminescent functional layer includes at least one of a hole injection layer, a hole transport layer or an electron blocking layer.

Optionally, in the above-mentioned quantum dot light-emitting device according to an embodiment of the disclosure, when the electron transport layer is included, a material of the electron transport layer includes at least one of zinc oxide, magnesium zinc oxide, aluminum zinc oxide, tin oxide or titanium oxide.

Optionally, in the above-mentioned quantum dot light-emitting device according to an embodiment of the disclosure, when the hole transport layer is included, a material of the hole transport layer includes at least one of CBP, NPB, TPD, nickel oxide, tungsten oxide, molybdenum oxide, cuprous oxide or vanadium oxide.

Optionally, in the above-mentioned quantum dot light-emitting device according to an embodiment of the disclosure, a material of the substrate is glass, polyimide or silicon wafer, and the azobenzene compound layer closest to the substrate is in direct contact with the substrate.

Correspondingly, an embodiment of the disclosure further provides a display device, including the quantum dot light-emitting device described in any one of embodiments of the disclosure.

Correspondingly, an embodiment of the disclosure further provides a method for patterning a quantum dot layer, including: forming an azobenzene compound layer with a trans structure on a substrate; forming a quantum dot film layer on the azobenzene compound layer, and curing quantum dots in a reserved area of the quantum dot film layer; developing the cured quantum dot film layer using a first solvent, and irradiating the azobenzene compound layer using ultraviolet light, so that irradiated azobenzene compound changes from a trans structure to a cis structure, to completely remove quantum dots outside the reserved area and form a patterned quantum dot layer in the reserved area.

Optionally, in the above-mentioned method for patterning the quantum dot layer according to an embodiment of the disclosure, developing the cured quantum dot film layer using the first solvent, and irradiating the azobenzene compound layer using the ultraviolet light, includes: developing the cured quantum dot film layer for a first time using the first solvent, to remove the quantum dots outside the reserved area; developing the cured quantum dot film layer for a second time using the first solvent, and simultaneously irradiating the azobenzene compound layer using the ultraviolet light.

Optionally, in the above-mentioned method for patterning the quantum dot layer according to an embodiment of the disclosure, developing the cured quantum dot film layer using the first solvent, and irradiating the azobenzene compound layer using the ultraviolet light, includes: developing the cured quantum dot film layer using the first solvent, and simultaneously irradiating the azobenzene compound layer using the ultraviolet light.

Optionally, in the above-mentioned method for patterning the quantum dot layer according to an embodiment of the disclosure, forming the quantum dot film layer on the azobenzene compound layer, and curing the quantum dots in the reserved area of the quantum dot film layer, includes: forming a quantum dot film layer with cross-linkable ligands on the azobenzene compound layer; irradiating the quantum dots in the reserved area using light of a predetermined wavelength, so that ligands on surfaces of the quantum dots in the reserved area are cross-linked to cure the quantum dots in the reserved area.

Optionally, in the above-mentioned method for patterning the quantum dot layer according to an embodiment of the disclosure, the cross-linkable ligands include at least one of 2-propene-1-thiol, isopentenyl thiol, N,N-methylene bisacrylamide, 1,6-hexanediol diacrylate, or diallyl sulfide.

Optionally, in the above-mentioned method for patterning the quantum dot layer according to an embodiment of the disclosure, forming the quantum dot film layer on the azobenzene compound layer, and curing the quantum dots in the reserved area of the quantum dot film layer, includes: forming a quantum dot film layer with a photosensitive material and with ligands on a surface thereof on the azobenzene compound layer; irradiating the quantum dots in the reserved area using light of a predetermined wavelength; where the photosensitive material or a product of the photosensitive material after irradiation of the light reacts with ligands on surfaces of the quantum dots under irradiation of the light of the preset wavelength, to make the ligands fall off from the surfaces of the quantum dots to change solubility of the quantum dots in the reserved area, and make the quantum dots in the reserved area coagulate to cure the quantum dots in the reserved area.

Optionally, in the above-mentioned method for patterning the quantum dot layer according to an embodiment of the disclosure, the ligands on the surfaces of the quantum dots include at least one of oleic acid, oleylamine, trioctylphosphine, or dodecanethiol.

Optionally, in the above-mentioned method for patterning the quantum dot layer according to an embodiment of the disclosure, the photosensitive material includes a photoacid generator, an olefin-like substance or an alkyne-like substance.

Optionally, in the above-mentioned method for patterning the quantum dot layer according to an embodiment of the disclosure, forming the azobenzene compound layer with the trans structure on the substrate, includes: forming the azobenzene compound layer on the substrate through spin coating, spray coating, blade coating or vapor deposition.

Optionally, in the above-mentioned method for patterning the quantum dot layer according to an embodiment of the disclosure, irradiating the azobenzene compound layer using the ultraviolet light, includes: irradiating the azobenzene compound layer from a side of the quantum dot film layer using the ultraviolet light.

Correspondingly, an embodiment of the disclosure further provides a manufacturing method of a quantum dot light-emitting device, including: forming a quantum dot layer on a substrate by using the method for patterning the quantum dot layer described in any one of embodiments of the disclosure.

Optionally, in the above-mentioned manufacturing method according to an embodiment of the disclosure, forming the quantum dot light-emitting device, includes: forming a first electrode on the substrate by using a patterning process; forming a first luminescent functional film layer on the first electrode; forming an azobenzene compound layer with a trans structure on the first luminescent functional film layer; forming a quantum dot film layer on the azobenzene compound layer, and curing quantum dots in a reserved area of the quantum dot film layer; developing the cured quantum dot film layer using a first solvent, and irradiating the azobenzene compound layer using ultraviolet light, so that irradiated azobenzene compound changes from a trans structure to a cis structure, to completely remove quantum dots outside the reserved area and form a patterned quantum dot layer in the reserved area; forming a second luminescent functional film layer on the quantum dot layer; forming a second electrode on the second luminescent functional film layer.

### BRIEF DESCRIPTION OF DRAWINGS

FIG. 1 is a schematic structural diagram of a quantum dot light-emitting device according to an embodiment of the disclosure;

FIG. 2 is a switching mechanism of cis and trans isomers after the azobenzene compound is irradiated by UV;

FIG. 3 is a schematic diagram of effects of pulling up, sliding and rolling of the quantum dots after the azobenzene compound is irradiated by UV;

FIG. 4 is a schematic structural diagram of a quantum dot light-emitting device with an upright structure according to an embodiment of the disclosure;

FIG. 5 is a schematic structural diagram of a quantum dot light-emitting device with an inverted structure according to an embodiment of the disclosure;

FIG. 6 is a schematic flowchart of a method for patterning a quantum dot layer according to an embodiment of the disclosure;

FIGS. 7A-7T are structural schematic diagrams of preparation steps in the method for patterning the quantum dot layer according to an embodiment of the disclosure;

FIG. 8 is a cross-linked network structure formed after cross-linkable ligands are cross-linked;

FIG. 9 is an emission spectrogram of a green second quantum dot unit;

FIG. 10 is an emission spectrogram of a blue third quantum dot unit;

FIG. 11 is a schematic flowchart of a manufacturing method of a quantum dot light-emitting device according to an embodiment of the disclosure;

FIG. 12 is a schematic structural diagram of a display device according to an embodiment of the disclosure.

### DETAILED DESCRIPTION OF EMBODIMENTS

In order to make the purposes, technical solutions and advantages of the disclosure clearer, technical solutions of embodiments of the disclosure will be described clearly and completely below in combination with the accompanying drawings of embodiments of the disclosure. Obviously the described embodiments are a part of embodiments of the disclosure but not all embodiments. Also in the case of no conflict, embodiments and features therein in the disclosure can be combined with each other. Based upon embodiments of the disclosure, all of other embodiments obtained by those ordinary skilled in the art without creative work pertain to the protection scope of the disclosure.

Unless otherwise defined, technical or scientific terms used in the disclosure shall have the general meaning understood by those ordinary skilled in the art to which the disclosure belongs. The word such as “include” or “contain” or the like used in the disclosure means that the element or object appearing before this word encompasses the elements or objects and their equivalents listed after this word, without excluding other elements or objects. The word such as “connect” or “connected” or the like is not limited to the physical or mechanical connection, but can include the electrical connection, whether direct or indirect. The words such as “inner”, “outer”, “up”, “down” are only used to represent the relative position relationship. When the absolute position of a described object changes, the relative position relationship may also change accordingly.

It should be noted that the size and shape of each diagram in the accompanying drawings do not reflect the true proportion, and are merely for purpose of schematically illustrating the content of the disclosure. Also, the same or similar reference numbers represent the same or similar elements or the elements having the same or similar functions all the way.

At present, it has become an important issue to prepare high-resolution QLED using a photolithography patterning process of quantum dots. However, in an existing process of directly patterning quantum dots, it is easy to form residues after a development process, resulting in a color mixing problem in a full-color display of quantum dots, reducing a color purity of a QLED device, and finally leading to a reduction in a color gamut of a display panel.

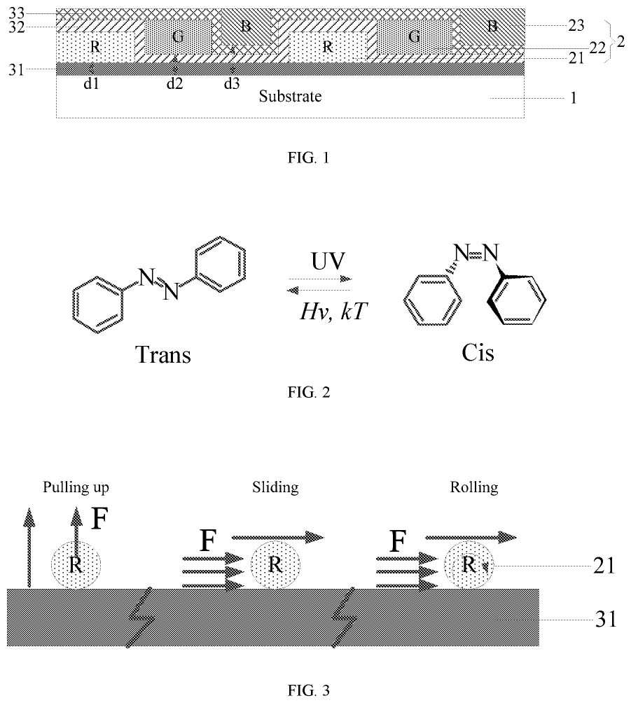

In view of this problem, an embodiment of the disclosure provides a quantum dot light-emitting device, as shown in FIG. 1, including: a substrate 1; a quantum dot layer 2 located on the substrate 1; where the quantum dot layer 2 includes a first quantum dot unit 21, a second quantum dot unit 22 and a third quantum dot unit 23 that emit light of different colors, orthographic projections of the first quantum dot unit 21, the second quantum dot unit 22 and the third quantum dot unit 23 on the substrate 1 do not overlap with each other, and distances (d1, d2, d3) between a bottom surface of the first quantum dot unit 21 and a surface of the substrate 1, between a bottom surface of the second quantum dot unit 22 and the surface of the substrate 1, and between a bottom surface of the third quantum dot unit 23 and the surface of the substrate 1 increase sequentially; where: an azobenzene compound layer (31, 32 and 33) is arranged between the substrate 1 and the first quantum dot unit 21, between the first quantum dot unit 21 and the second quantum dot unit 22, and between the second quantum dot unit 22 and the third quantum dot unit 23, an orthographic projection of the azobenzene compound layer (31, 32 and 33) on the substrate 1 completely covers the substrate 1, and an azobenzene compound of the azobenzene compound layer (31, 32 and 33) has a trans structure.

In the above-mentioned quantum dot light-emitting device according to an embodiment of the disclosure, before fabricating the patterned first quantum dot unit 21, before fabricating the patterned second quantum dot unit 22 and before fabricating the patterned third quantum dot unit 23, it is necessary to spin-coat a whole quantum dot film layer respectively and then fabricate each quantum dot unit through the photolithography patterning process. In the disclosure, an azobenzene compound layer is arranged between the substrate 1 and the first quantum dot unit 21, between the first quantum dot unit 21 and the second quantum dot unit 22, and between the second quantum dot unit 22 and the third quantum dot unit 23, so that an azobenzene compound layer 3 can be deposited before the first quantum dot film layer is spin coated, before the second quantum dot film layer is spin coated and before the third quantum dot film layer is spin coated, and then each quantum dot unit is fabricated through the photolithography patterning process. Since a development process is required for the quantum dot units to be reserved after irradiation during the photolithographic patterning process, the disclosure may irradiate the azobenzene compound layer using the ultraviolet light while developing, or firstly develop the quantum dot units for the first time and then develop the quantum dot units for the second time, and irradiate the azobenzene compound layer using the ultraviolet light while developing for the second time. Due to the characteristic that the azobenzene compound with a trans structure may undergo a cis-trans isomer conversion under ultraviolet (UV) irradiation, the azobenzene compound with the trans structure becomes a cis structure, as shown in FIG. 2, and FIG. 2 is a switching mechanism of cis and trans isomers after the azobenzene compound is irradiated by UV. In the process of the isomer conversion of the azobenzene compound, a molecular-level interfacial force F may be generated, to make the quantum dots remaining on the surface of the azobenzene compound layer (taking 31 as an example) slide, roll or pull up, as shown in FIG. 3. The adhesion between the quantum dots (21) and the surface of the azobenzene compound layer 31 can be reduced to completely remove the quantum dots outside the reserved area, thereby effectively solving the problem of residue of the quantum dot layer in the photolithographic development process, preventing the occurrence of color mixing, and improving the performance of the quantum dot light-emitting device prepared by the photolithographic patterning process.

As shown in FIG. 2, the azobenzene compound with the stable trans structure becomes the cis structure under ultraviolet (UV) irradiation. When the ultraviolet light is removed, that is, at room temperature (hv), the azobenzene compound with the cis structure becomes the stable trans structure.

As shown in FIG. 1, in an embodiment of the disclosure, the color of the light emitted by the first quantum dot unit 21, the color of the light emitted by the second quantum dot unit 22, and the color of the light emitted by the third quantum dot unit 23 are red (R), green (G) and blue (B) respectively. Of course, the quantum dot layer 2 provided in an embodiment of the disclosure may also include quantum dot units emitting light of other colors, such as yellow, which is not limited in an embodiment of the disclosure.

An embodiment of the disclosure does not limit a material of the azobenzene compound, and the material of the azobenzene compound may be azobenzene, 4-aminoazobenzene, azobenzene-4,4-dicarboxylic acid, 4,4′-dihydroxyazo benzene, p-diaminoazobenzene, 4-(phenylazo)benzoic acid, 4-phenylazo phenol, 4,4′-azoxybenzene methyl ether, 2-(p-hydroxy phenylazo)benzoic acid, 4-methoxy azobenzene, 4-(diethylamino)azobenzene, 4,4′-bis(hexyloxy)azoxybenzene, azoxybenzene, azobenzene-3,3′-dicarboxylic acid, 4-dimethylamino azobenzene-4′-formic acid, 4-(phenylazo)diphenylamine, azobenzene-4,4′-dicarbonyl acyl chloride, 4-phenylazo benzoyl chloride, 4-hydroxy azobenzene-4′-sulfonyl sodium hydrate, 4-(4-bromine phenylazo)phenol, 3′-nitro-4-dimethylamino azobenzene, 4-amino-4′-dimethylamino azobenzene, 3,3′-dimethyl azobenzene, 4-acetylamino-2′, 3-dimethyl azobenzene, 4-(4-nitro phenylazo)resorcinol, 2-carbamoyl-2-(phenylazo)acetamidine, 4-phenylazo-1-naphthylamine, 4-(2-thiazolylazo)resorcinol, 4-hydroxy-4′-dimethylamino azobenzene, azobenzene-4,4′-dimethyl dicarboxylate, 4-(dimethylamino)-2-methyl azobenzene, 4-(4-dimethylamino phenylazo)benzenearsonate, 4-phenylazo thiocyanate, dimethylamino phenylazobenzene sulfonyl-L-leucine, 4-(4-diethylamino phenylazo)pyridine, 4,4′-dipentyloxy azoxybenzene, etc., or azobenzene derivatives thereof, etc.

An embodiment of the disclosure does not limit a material of the quantum dot, and the material of the quantum dot may be CdS, CdSe, ZnSe, InP, PbS, CsPbCl₃, CsPbBr₃, CsPhI₃, CdS/ZnS, CdSe/ZnS, InP/ZnS, PbS/ZnS, CsPbCl₃/ZnS, CsPbBr₃/ZnS, CsPhI₃/ZnS or other quantum dots.

During a specific implementation, in the above-mentioned quantum dot light-emitting device according to an embodiment of the disclosure, as shown in FIG. 1, a thickness of each azobenzene compound layer (31, 32 and 33) may be in a range of 1 nm to 10 nm. A continuous and uniform film layer may be formed under this thickness, and can be well attached to the surface of the substrate 1, block the direct contact between the quantum dots and the substrate, provide the sufficient interfacial force in the development process of the quantum dots, and remove the residual quantum dots. Too thin film layer cannot form a continuous thin film, so that some quantum dots are in direct contact with the substrate 1 and difficult to be removed in the development process; the too thick film layer can form a complete film layer and remove the residual quantum dots, but the too thick film layer affects the transport performance of carriers in the quantum dot light-emitting device and then affects the performance of the quantum dot light-emitting device.

It should be noted that the thickness of the azobenzene compound layer in the quantum dot light-emitting device according to an embodiment of the disclosure is set in the range of 1 nm to 10 nm, where the film layer is relatively thin and may not affect the light-emitting performance of the quantum dot layer.

During a specific implementation, in the above-mentioned quantum dot light-emitting device according to an embodiment of the disclosure, as shown in FIG. 1, a surface of the third quantum dot unit 23 is flush with a surface of the azobenzene compound layer 33 farthest from the substrate 1. In this way, when a subsequent film layer is fabricated, flatness of the subsequent film layer can be ensured, and the device performance can be improved.

During a specific implementation, in the above-mentioned quantum dot light-emitting device according to an embodiment of the disclosure, as shown in FIG. 1, the quantum dot layer 2 is a film layer after ligands on surfaces of quantum dots are cross-linked. For example, when a patterned quantum dot unit is fabricated using the photolithographic patterning process, a surface of the quantum dot has a ligand that can be cross-linked under irradiation of the light of a preset wavelength, so that the quantum dots in the quantum dot reserved area can be irradiated, and the remaining areas are covered by a mask plate. The ligands on the surfaces of the irradiated quantum dots are cross-linked to form a stable cross-linked network structure, which is insoluble in the developing solvent, while the quantum dots that are not irradiated are washed away by the solvent, thus forming the patterned quantum dots, so the patterned quantum dot layer is a film layer after the ligands on the surfaces of the quantum dots are cross-linked.

Of course, when the patterned quantum dot unit is fabricated using the photolithographic patterning process, the quantum dot film layer with a photosensitive material may be spin-coated. Under irradiation of the light of the preset wavelength, the photosensitive material or a product of the photosensitive material after light irradiation reacts with the ligands on the surfaces of the quantum dots, to make the ligands fall off from the surfaces of the quantum dots to change the solubility of the quantum dots in the reserved area, and make the quantum dots in the reserved area coagulate to cure the quantum dots in the reserved area. That is, the quantum dot layer may also be a film layer after the ligands on the surfaces of the quantum dots fall off.

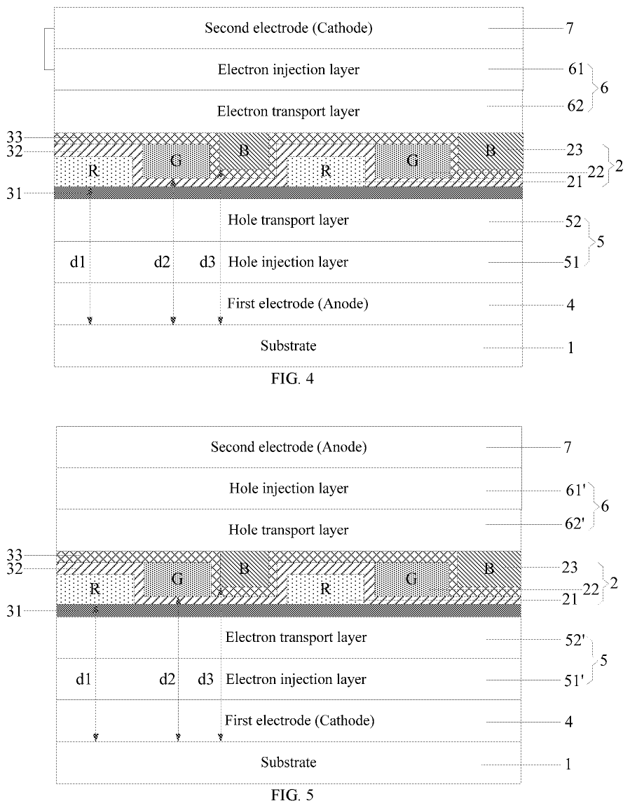

During a specific implementation, in the above-mentioned quantum dot light-emitting device according to an embodiment of the disclosure, as shown in FIGS. 4 and 5, the azobenzene compound layer between the substrate 1 and the first quantum dot unit 21 is a first azobenzene compound layer 31, and the quantum dot light-emitting device further includes: a first electrode 4 located between the substrate 1 and the first azobenzene compound layer 31, a first luminescent functional layer (5 and 5′) located between the first electrode 4 and the first azobenzene compound layer 31, a second luminescent functional layer (6 and 6′) located on a side of the quantum dot layer 2 away from the substrate 1, and a second electrode 7 located on a side of the second luminescent functional layer (6 and 6′) away from the substrate 1.

An embodiment of the disclosure does not limit the structure of the quantum dot light-emitting device, and the quantum dot light-emitting device may be a device with an upright structure or a device with an inverted structure. The difference between the upright structure and the inverted structure is that the fabrication order of the film layers is different. The upright structure is forming an anode, a hole injection layer, a hole transport layer, a quantum dot layer, an electron transport layer, an electron injection layer and a cathode sequentially on the substrate; and the inverted structure is forming a cathode, an electron injection layer, an electron transport layer, a quantum dot layer, a hole transport layer, a hole injection layer and an anode sequentially on the substrate.

During a specific implementation, in the above-mentioned quantum dot light-emitting device according to an embodiment of the disclosure, as shown in FIG. 4, the quantum dot light-emitting device is an upright structure, that is, the first electrode 4 is an anode, the second electrode 7 is a cathode, the first luminescent functional layer 5 may include at least one of a hole injection layer 51, a hole transport layer 52 or an electron blocking layer, and the second luminescent functional layer 6 may include at least one of an electron injection layer 61, an electron transport layer 62 or a hole blocking layer. In an embodiment of the disclosure, FIG. 4 shows that the first luminescent functional layer 5 includes a hole injection layer 51 and a hole transport layer 52, and the second luminescent functional layer 6 includes an electron injection layer 61 and an electron transport layer 62. Of course, layers of the hole injection layer, the hole transport layer, the electron blocking layer, the electron injection layer, the electron transport layer and the hole blocking layer may be selected and arranged as required.

During a specific implementation, in the above-mentioned quantum dot light-emitting device according to an embodiment of the disclosure, as shown in FIG. 5, the quantum dot light-emitting device is an inverted structure, that is, the first electrode 4 is a cathode, the second electrode 7 is an anode, the first luminescent functional layer 5′ may include at least one of an electron injection layer 51′, an electron transport layer 52′ or a hole blocking layer, and the second luminescent functional layer 6′ may include at least one of a hole injection layer 61′, a hole transport layer 62′ or an electron blocking layer. In an embodiment of the disclosure, FIG. 5 shows that the first luminescent functional layer 5′ includes an electron injection layer 51′ and an electron transport layer 52′, and the second luminescent functional layer 6′ includes a hole injection layer 61′ and a hole transport layer 62′. Of course, layers of the hole injection layer, the hole transport layer, the electron blocking layer, the electron injection layer, the electron transport layer and the hole blocking layer may be selected and arranged as required.

During a specific implementation, in the above-mentioned quantum dot light-emitting device according to an embodiment of the disclosure, as shown in FIGS. 4 and 5, when the electron transport layer (62, 52′) is included, a material of the electron transport layer (62, 52′) may include but not limited to at least one of zinc oxide, magnesium zinc oxide, aluminum zinc oxide, tin oxide or titanium oxide.

During a specific implementation, in the above-mentioned quantum dot light-emitting device according to an embodiment of the disclosure, as shown in FIGS. 4 and 5, when the hole transport layer (52, 62′) is included, a material of the hole transport layer (52, 62′) may include but not limited to at least one of CBP, NPB, TPD, nickel oxide, tungsten oxide, molybdenum oxide, cuprous oxide or vanadium oxide. The CBP, NPB and TPD are organic hole transport materials, and the nickel oxide, tungsten oxide, molybdenum oxide, cuprous oxide and vanadium oxide are inorganic hole transport materials.

During a specific implementation, in the above-mentioned quantum dot light-emitting device according to an embodiment of the disclosure, as shown in FIGS. 4 and 5, the substrate 1 may include a base substrate, a drive circuit located on the base substrate, and a passivation layer, a flat layer and other structures located above the drive circuit.

The light emitting mode of the quantum dot light-emitting device shown in FIG. 4 and FIG. 5 provided by embodiments of the disclosure may be emitting light from bottom or emitting light from top. Whether the light emitting mode is emitting light from bottom or emitting light from top may be set by selecting materials of the first electrode and the second electrode.

FIG. 4 and FIG. 5 show further specific structures in the case where the quantum dot light-emitting device shown in FIG. 1 is an electroluminescent device as an example. Of course, the quantum dot light-emitting device shown in FIG. 1 provided by an embodiment of the disclosure may also be a photoluminescent device, so that the azobenzene compound layer 31 closest to the substrate 1 is in direct contact with the substrate 1. A material of the substrate 1 is not limited in the photoluminescent device. For example, the material of the substrate 1 may be glass, polyimide (PI) or silicon wafer, etc.

During a specific implementation, the quantum dot light-emitting device according to an embodiment of the disclosure may also include other functional film layers well known to those skilled in the art, which will not be described in detail here.

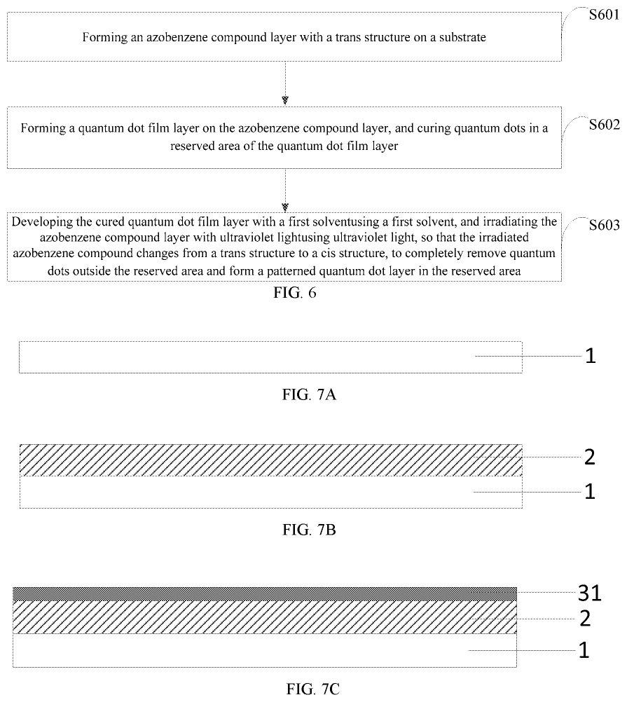

Based on the same inventive concept, an embodiment of the disclosure further provides a method for patterning a quantum dot layer, as shown in FIG. 6, including following steps.

S601: forming an azobenzene compound layer with a trans structure on a substrate.

S602: forming a quantum dot film layer on the azobenzene compound layer, and curing quantum dots in a reserved area of the quantum dot film layer.

S603: developing the cured quantum dot film layer using a first solvent, and irradiating the azobenzene compound layer using ultraviolet light, so that irradiated azobenzene compound changes from a trans structure to a cis structure, to completely remove quantum dots outside the reserved area and form a patterned quantum dot layer in the reserved area.

In the above method for patterning the quantum dot layer according to an embodiment of the disclosure, before forming the quantum dot film layer, an azobenzene compound layer is deposited firstly, and then a patterned quantum dot layer is fabricated through a photolithographic patterning process. The azobenzene compound layer is irradiated by ultraviolet light when developing, and the azobenzene compound with the trans structure may undergo a cis-trans isomer conversion under ultraviolet irradiation, that is, the azobenzene compound with the trans structure becomes a cis structure. In the process of the isomer conversion of the azobenzene compound, the molecular-level interfacial force may be generated, to make the quantum dots remaining on the surface of the azobenzene compound layer slide, roll or pull up. The adhesion between the quantum dots and the surface of the azobenzene compound layer can be reduced to completely remove the quantum dots outside the reserved area, thereby effectively solving the problem of residue of the quantum dot layer in the photolithographic development process, preventing the occurrence of color mixing, and improving the performance of the quantum dot light-emitting device prepared through the photolithographic patterning process.

It should be noted that an embodiment of the disclosure describes the method for patterning the quantum dot layer in detail by mainly taking the light-emitting device with the inverted structure as shown in FIG. 5 as an example.

In order to realize the full-color display, the quantum dot layer generally includes patterned quantum dot units of different colors. In an embodiment of the disclosure, taking the quantum dot layer including a first quantum dot unit, a second quantum dot unit and a third quantum dot unit as an example, the method for patterning the quantum dot layer provided by an embodiment of the disclosure will be introduced in detail with reference to the accompanying drawings.

Quantum dot solutions are prepared. Taking the quantum dot being CdSe as an example, the first quantum dot solution, the second quantum dot solution and the third quantum dot solution of different colors are prepared respectively. The CdSe quantum dots can be formed by but not limited to solution phase synthesis method, hydrothermal method, solvothermal method, etc.; and the ligands on the surfaces of the CdSe quantum dots may include at least one of oleic acid, oleylamine, trioctylphosphine, or dodecanethiol, etc.

Taking the ligand on the surface of the quantum dot CdSe prepared above being oleic acid as an example, since the oleic acid cannot be cross-linked, it is necessary to replace the oleic acid ligand with the cross-linkable ligand, such as 2-propene-1-thiol ligand. The process of preparing a quantum dot with 2-propene-1-thiol ligand on the surface is as follows.

The exchange process of ligands of CdSe quantum dots needs to be carried out under the protection of nitrogen environment, and water and oxygen-free ultra-dry solvent is used during the experiment. The solvent of quantum dots with oleic acid ligands (30 mg/mL, 5 mL) is removed by a rotary evaporator, and is redissolved with 5 mL chloroform and added to a 20 mL reflux bottle equipped with magnetic stirring. The temperature is raised to 65° C., and 5 mL chloroform solution of 0.5 g 2-propene-1-thiol ligands is slowly added dropwise to the quantum dot solution 3 times with an interval of 1 h and finally refluxed for 1 h, the reaction is ended and the room temperature is cooled. An appropriate amount of acetone is added to the reaction system, the quantum dots are settled and centrifuged, and the precipitate is dissolved with toluene. Then the process is cycled with acetone/toluene for 3 times to clean the residual oleic acid and unmodified ligands on the surfaces of the quantum dots. The quantum dots CdSe with 2-propene-1-thiol ligands are obtained, and stored in a refrigerator at 0 to 5° C. 1 to 5% photoinitiator (benzophenone) is added for mixing well before use.

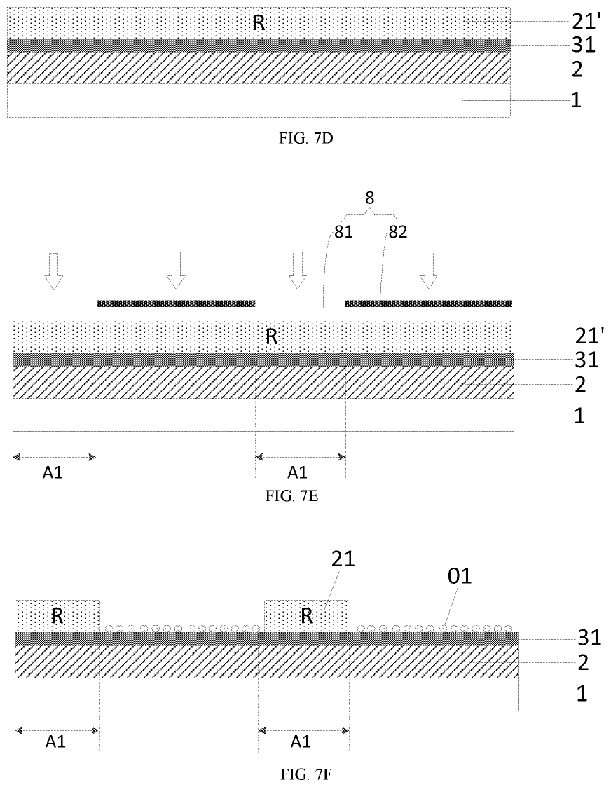

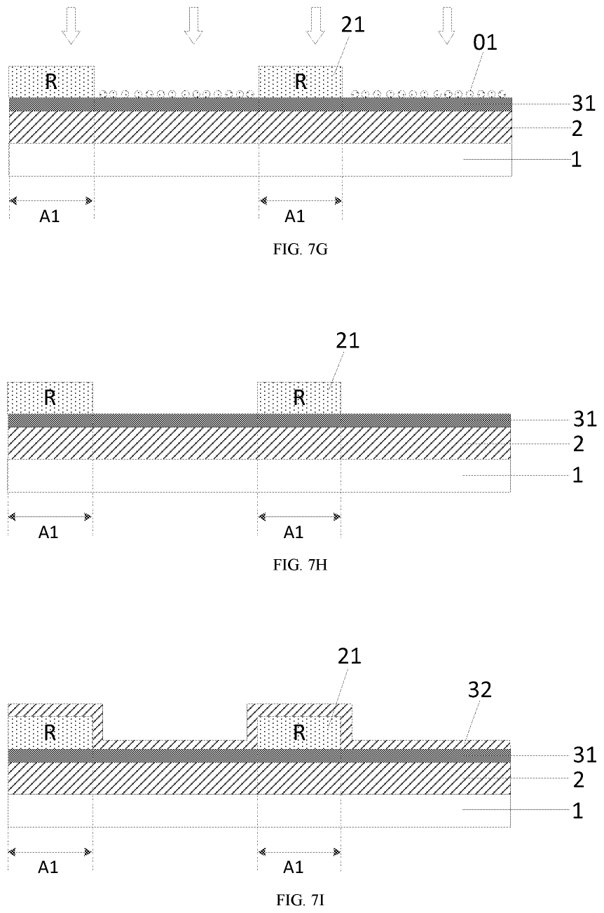

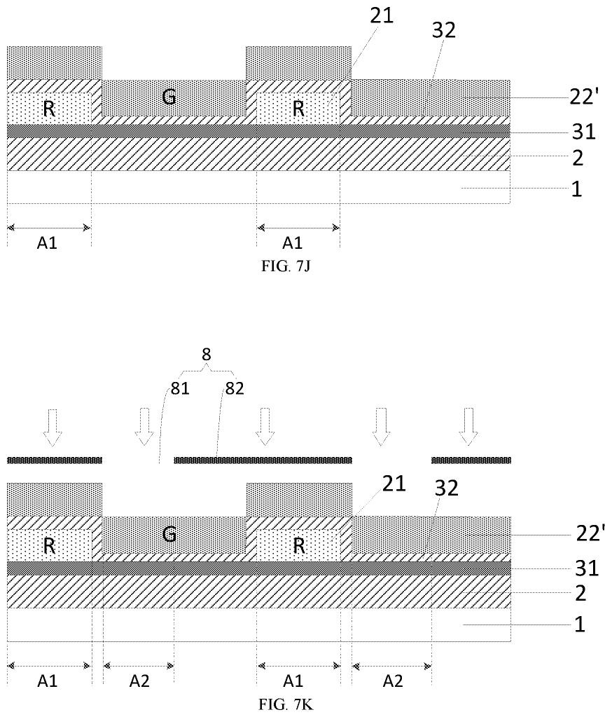

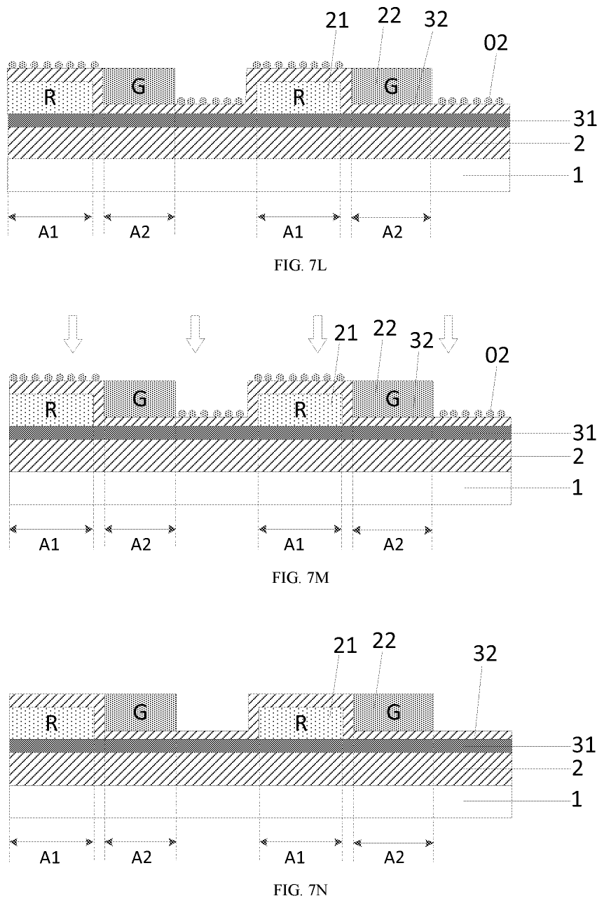

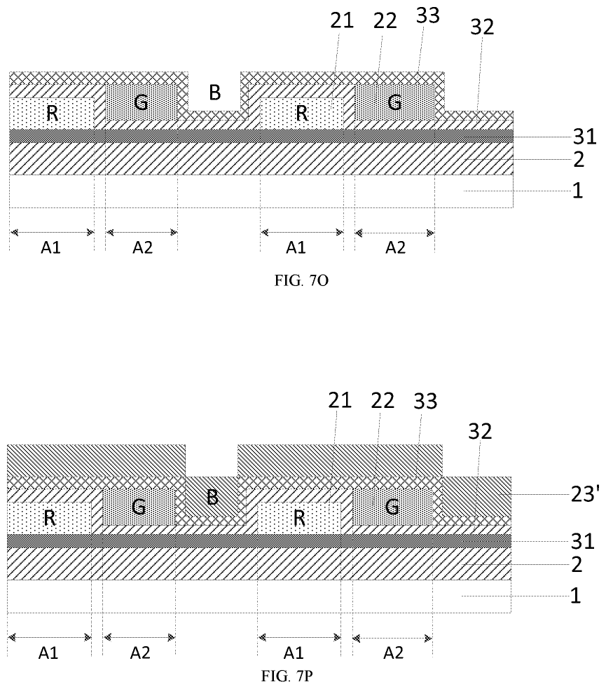

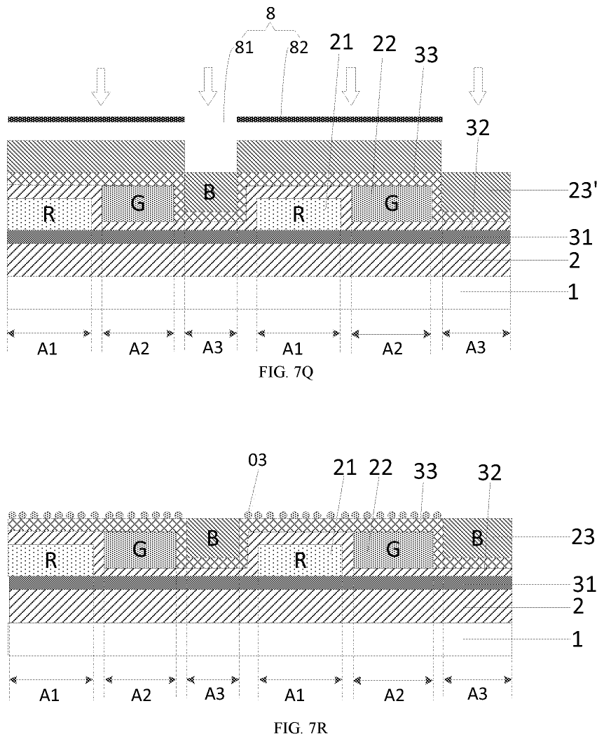

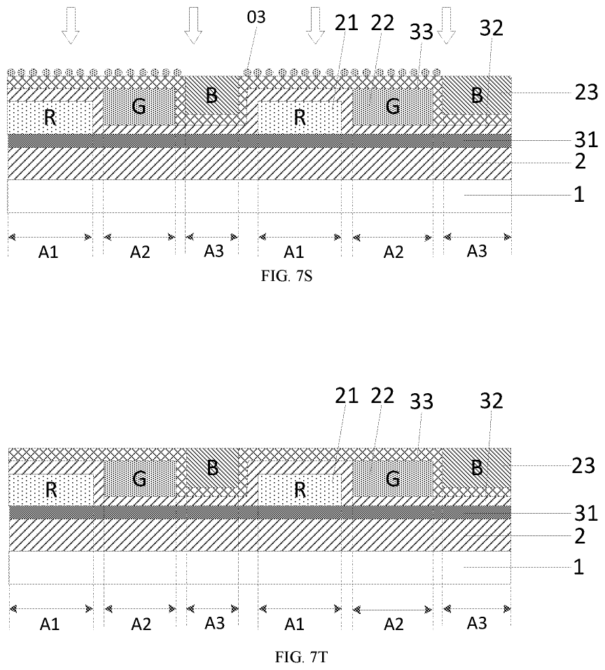

As shown in FIG. 7A, a substrate 1 is provided, and the substrate 1 is cleaned and dried. The substrate 1 may include a base substrate, a drive circuit located on the base substrate, and a passivation layer, a flat layer and other structures located above the drive circuit.

As shown in FIG. 7B, a first electrode 4 and an electron injection layer 51′ are formed on the substrate 1, and then an electron transport layer 52′ is deposited on the substrate 1 through spin coating (sputter) or sol-gel method (sol-gel); and the disclosure only illustrates the electron transport layer 52′ on the substrate 1. The material of the electron transport layer 52′ may be ZnO.

As shown in FIG. 7C, a trans-structure azobenzene compound layer 31 is deposited on the electron transport layer 52′ through spin coating, spray coating, blade coating or vapor deposition. The structure of the azobenzene compound is as shown on the left side of FIG. 2. The thickness of the azobenzene compound layer 31 is, for example, 5 nm. The solvent in the solution of the spin-coated azobenzene compound layer 31 is chloroform, the solution concentration is 15 mg/L, and the spin coating speed is 3000 r/min.

As shown in FIG. 7D, a first quantum dot film layer 21′ with cross-linkable ligands is formed on the azobenzene compound layer 31, where the cross-linkable ligands are 2-propene-1-thiol ligands.

As shown in FIG. 7E, the first quantum dots in the first quantum dot reserved area A1 are irradiated using light of a preset wavelength (ultraviolet light, shown by the direction of the arrow in the figure), and the first quantum dot reserved area A1 corresponds to an area that needs to form the first quantum dot unit 21 later, so that the ligands on the surfaces of the first quantum dots in the first reserved area A1 are cross-linked to cure the first quantum dots in the first reserved area A1; the exposure time may be 30 s, and the exposure intensity may be in a range of 1 to 50 mw/cm². During a specific implementation, in the above-mentioned patterning method according to an embodiment of the disclosure, the first quantum dot film layer 21′ may be irradiated using the ultraviolet light. When the first quantum dot film layer 21′ is irradiated, the first quantum dot film layer 21′ may be blocked by a mask plate 8. The mask plate 8 includes a light-transmitting area 81 and a light-shielding area 82, and the light-transmitting area 81 corresponds to the first quantum dot reserved area A1 irradiated by light in the first quantum dot film layer 21′.

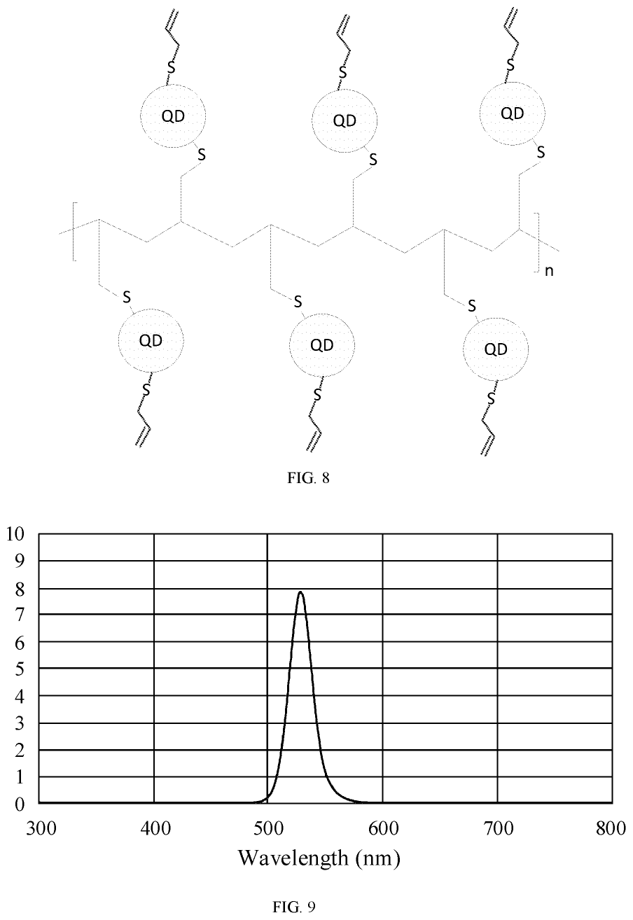

As shown in FIG. 7F, the first solvent (toluene and chloroform with a volume ratio of 3:1) is used to develop the cured first quantum dot film layer 21′ for the first time, and the first quantum dots in the area that is not irradiated by the ultraviolet light in the first quantum dot film layer 21′ are dissolved in the first solvent and washed away, while the 2-propene-1-thiol ligands on the surfaces of the first quantum dots in the first quantum dot reserved area A1 are cross-linked, to form a stable cross-linked network structure insoluble in the first solvent, and form a patterned first quantum dot unit 21. The cross-linked network structure is as shown in FIG. 8, where QD represents a quantum dot.

As shown in FIG. 7F, the first quantum dots are likely to remain in the area outside the first reserved area A1 in the first development process (01 represents the remaining first quantum dots); and as shown in FIG. 7G, the first solvent is used to develop the cured first quantum dot film layer 21′ for the second time while the azobenzene compound layer 31 is irradiated using the ultraviolet light (shown by the arrow) from a side of the first quantum dot film layer 21′, where the azobenzene compound with the trans structure becomes the cis structure, as shown in FIG. 2. In the process of the isomer conversion of the azobenzene compound, an interfacial force F at the molecular level may be generated to make the remaining quantum dots on the surface of the azobenzene compound layer 31 slide, roll or pull up, as shown in FIG. 3. The adhesion between the remaining first quantum dots 01 and the surface of the azobenzene compound layer 31 can be reduced to completely remove the remaining first quantum dots 01 outside the first reserved area A1, as shown in FIG. 7H.

It should be noted that, when the azobenzene compound layer 31 is irradiated using the ultraviolet light (shown by the arrow), the first quantum dot unit 21 in the first reserved area A1 can play a blocking role, so the azobenzene compound layer 31 under the first reserved area A1 will not perform the cis-trans isomer conversion, and thus the first quantum dot unit 21 in the first reserved area A1 may not be developed.

It should be noted that the solvent of the first quantum dot material provided in an embodiment of the disclosure is toluene and chloroform, so the toluene and chloroform can be used to clean the first quantum dot film layer 21′ after being irradiated by light of the preset wavelength. Of course, the solvent may also be a mixed solvent of one or more of chlorobenzene, tetrahydrofuran, n-hexane, n-heptane or n-octane.

It should be noted that, in an embodiment of the disclosure, two development processes are used for the first quantum dots after light irradiation, and the azobenzene compound layer is irradiated using the ultraviolet light simultaneously during the second development. Of course, one development process may also be used, where the cured quantum dot film layer is developed using the first solvent while the azobenzene compound layer is irradiated using the ultraviolet light.

Cross-linkable ligands on the surfaces of the quantum dots are not limited to 2-propene-1-thiol, and may also include at least one of isopentenyl thiol, N,N-methylene bisacrylamide, 1,6-hexanediol diacrylate, or diallyl sulfide.

It should be noted that the quantum dots are cured through cross-linking reaction as an example in an embodiment of the disclosure. Of course, the quantum dots may also be cured through the following methods.

A first quantum dot film layer with a photosensitive material and with ligands on a surface is formed on the azobenzene compound layer; and the first quantum dots in the first reserved area are irradiated using light of a preset wavelength (such as ultraviolet light). The photosensitive material or a product of the photosensitive material after light irradiation reacts with the ligands on the surfaces of the first quantum dots under irradiation of light of the preset wavelength, to make the ligands fall off from the surfaces of the first quantum dots to change the solubility of the first quantum dots in the first reserved area, and make the first quantum dots in the first reserved area coagulate to cure the first quantum dots in the first reserved area.

The above-mentioned ligands that can fall off may include but not limited to at least one of oleic acid, oleylamine, trioctylphosphine, or dodecanethiol.

The above-mentioned photosensitive material may include a photoacid generator, an olefin-like substance or an alkyne-like substance. When the photosensitive material is a photoacid generator, the photoacid generator generates hydrogen ions under the irradiation of ultraviolet light, and the hydrogen ions bind to the ligands on the surfaces of the first quantum dots, so that the ligands fall off from the surfaces of the first quantum dots. The solubility of the first quantum dots without ligands is different from the solubility of the first quantum dots with ligands, so that the first quantum dots without ligands in the first reserved area A1 can coagulate, to cure the first quantum dots in the first reserved area A1. When the photosensitive material is an olefin-like substance or an alkyne-like substance, the olefin-like substance or alkyne-like substance can directly bind to the ligands on the surfaces of the first quantum dots, so that the ligands fall off from the surface of the first quantum dots, to cure the first quantum dots in the first reserved area A1.

Optionally, the photoacid generator may include at least one of sulfonium salt, triazine, sulfonate ester, or diazonium salt.

The sulfonium salt may be hexafluoroantimonate triphenyl sulfonium salt, etc.; the triazine may be (4,6)-bis(trichloromethyl)-1,3,5 triazine derivative, etc.; the sulfonate ester may be N-p-toluenesulfonyl oxygen phthalimide, etc.; and the diazonium salt may be diazonium fluoroborate, etc.

Next, as shown in FIG. 7I, a trans-structure azobenzene compound layer 32 is deposited on the first quantum dot unit 21 through spin coating, spray coating, blade coating or vapor deposition. The structure of the azobenzene compound is as shown on the left side of FIG. 2, where a thickness of the azobenzene compound layer 32 is, for example, 5 nm. Solvents in the solution of the spin-coated azobenzene compound layer 32 are toluene and chloroform, the solution concentration is 15 mg/L, and the spin coating speed is 3000 r/min.

As shown in FIG. 7J, a second quantum dot film layer 22′ with cross-linkable ligands is formed on the azobenzene compound layer 32, where the cross-linkable ligands are 2-propene-1-thiol ligands.

As shown in FIG. 7K, second quantum dots in the second quantum dot reserved area A2 are irradiated using light of a preset wavelength (ultraviolet light, shown by the direction of the arrow in the figure), and the second quantum dot reserved area A2 corresponds to an area that needs to form the second quantum dot unit 22 later, so that the ligands on the surfaces of the second quantum dots in the second reserved area A2 are cross-linked to cure the second quantum dots in the second reserved area A2. During a specific implementation, in the above-mentioned patterning method according to an embodiment of the disclosure, the second quantum dot film layer 22′ may be irradiated using the ultraviolet light. When the second quantum dot film layer 22′ is irradiated, the second quantum dot film layer 22′ may be blocked by a mask plate 8. The mask plate 8 includes a light-transmitting area 81 and a light-shielding area 82, and the light-transmitting area 81 corresponds to the second quantum dot reserved area A2 irradiated by light in the second quantum dot film layer 22′.

As shown in FIG. 7L, the first solvent (toluene and chloroform with a volume ratio of 3:1) is used to develop the cured second quantum dot film layer 22′ for the first time, and the second quantum dots in the area that is not irradiated by the ultraviolet light in the second quantum dot film layer 22′ are dissolved in the first solvent and washed away, while the 2-propene-1-thiol ligands on the surfaces of the second quantum dots in the second quantum dot reserved area A2 are cross-linked, to form a stable cross-linked network structure insoluble in the first solvent, and form a patterned second quantum dot unit 22. The cross-linked network structure is as shown in FIG. 8, where QD represents a quantum dot.

As shown in FIG. 7L, second quantum dots are likely to remain in the area outside the second reserved area A2 in the first development process (02 represents the remaining second quantum dots); and as shown in FIG. 7M, the first solvent is used to develop the cured second quantum dot film layer 22′ for the second time while the azobenzene compound layer 32 is irradiated using the ultraviolet light (shown by the arrow) from a side of the second quantum dot film layer 22′, where the azobenzene compound with the trans structure becomes the cis structure, as shown in FIG. 2. In the process of the isomer conversion of the azobenzene compound, an interfacial force F at the molecular level may be generated to make the remaining quantum dots on the surface of the azobenzene compound layer 32 slide, roll or pull up, as shown in FIG. 3. The adhesion between the remaining second quantum dots 02 and the surface of the azobenzene compound layer 32 can be reduced to completely remove the remaining second quantum dots 02 outside the second reserved area A2, as shown in FIG. 7N.

It should be noted that, when the azobenzene compound layer 32 is irradiated using the ultraviolet light (shown by the arrow), the second quantum dot unit 22 in the second reserved area A2 can play a blocking role, so the azobenzene compound layer 32 in the second reserved area A2 may not perform the cis-trans isomer conversion, and thus the second quantum dot unit 22 in the second reserved area A2 may not be developed.

It should be noted that the solvent of the second quantum dot material provided in an embodiment of the disclosure is toluene and chloroform, so the toluene and chloroform may be used to clean the second quantum dot film layer 22′ after being irradiated by light of the preset wavelength. Of course, the solvent may also be a mixed solvent of one or more of chlorobenzene, tetrahydrofuran, n-hexane, n-heptane or n-octane.

Next, as shown in FIG. 7O, a trans-structure azobenzene compound layer 33 is deposited on the second quantum dot unit 22 through spin coating, spray coating, blade coating or vapor deposition. The structure of the azobenzene compound is as shown on the left side of FIG. 2, where a thickness of the azobenzene compound layer 33 is, for example, 5 nm. Solvents in the solution of the spin-coated azobenzene compound layer 33 are toluene and chloroform, the solution concentration is 15 mg/L, and the spin coating speed is 3000 r/min.

As shown in FIG. 7P, a third quantum dot film layer 23′ with cross-linkable ligands is formed on the azobenzene compound layer 33, and the cross-linkable ligands are 2-propene-1-thiol ligands.

As shown in FIG. 7Q, third quantum dots in the third quantum dot reserved area A3 are irradiated using light of a preset wavelength (ultraviolet light, shown by the direction of the arrow in the figure), and the third quantum dot reserved area A3 corresponds to an area that needs to form the third quantum dot unit 23 later, so that the ligands on the surfaces of the third quantum dots in the third reserved area A3 are cross-linked to cure the third quantum dots in the third reserved area A3. During a specific implementation, in the above-mentioned patterning method according to an embodiment of the disclosure, the third quantum dot film layer 23′ may be irradiated by the ultraviolet light. When the third quantum dot film layer 23′ is irradiated, the third quantum dot film layer 23′ may be blocked by a mask plate 8. The mask plate 8 includes a light-transmitting area 81 and a light-shielding area 82, and the light-transmitting area 81 corresponds to the third quantum dot reserved area A3 irradiated by light in the third quantum dot film layer 23′.

As shown in FIG. 7R, the first solvent (toluene and chloroform) is used to develop the cured third quantum dot film layer 23′ for the first time, and the third quantum dots in the area that is not irradiated by the ultraviolet light in the third quantum dot film layer 23′ are dissolved in the first solvent and washed away, while the 2-propene-1-thiol ligands on the surfaces of the third quantum dots in the third quantum dot reserved area A3 are cross-linked, to form a stable cross-linked network structure insoluble in the first solvent, and form a patterned third quantum dot unit 23. The cross-linked network structure is as shown in FIG. 8, and QD represents a quantum dot.

As shown in FIG. 7R, third quantum dots are likely to remain in the area outside the third reserved area A3 in the first development process (03 represents the remaining third quantum dots). As shown in FIG. 7S, the first solvent is used to develop the cured third quantum dot film layer 23′ for the second time while the azobenzene compound layer 33 is irradiated using the ultraviolet light (shown by the arrow) from a side of the third quantum dot film layer 23′, where the azobenzene compound with the trans structure becomes the cis structure, as shown in FIG. 2. In the process of the isomer conversion of the azobenzene compound, an interfacial force F at the molecular level may be generated to make the remaining quantum dots on the surface of the azobenzene compound layer 33 slide, roll or pull up, as shown in FIG. 3.

The adhesion between the remaining third quantum dots 03 and the surface of the azobenzene compound layer 33 can be reduced to completely remove the remaining third quantum dots 03 outside the third reserved area A3, as shown in FIG. 7T.

It should be noted that, when the azobenzene compound layer 33 is irradiated using the ultraviolet light (shown by the arrow), the third quantum dot unit 23 in the third reserved area A3 can play a blocking role, so the azobenzene compound layer 33 in the third reserved area A3 may not perform the cis-trans isomer conversion, and thus the third quantum dot unit 23 in the third reserved area A3 may not be developed.

It should be noted that the solvent of the third quantum dot material provided in an embodiment of the disclosure is toluene and chloroform, so the toluene and chloroform can be used to clean the third quantum dot film layer 23′ after being irradiated by light of the preset wavelength. Of course, the solvent may also be a mixed solvent of one or more of chlorobenzene, tetrahydrofuran, n-hexane, n-heptane or n-octane.

Therefore, the patterned quantum dot layer 2 provided in an embodiment of the disclosure is formed by the steps shown in FIGS. 7A-7T.

In a possible embodiment, the first quantum dot unit, the second quantum dot unit and the third quantum dot unit provided in an embodiment of the disclosure may be fabricated by irradiating the first quantum dot reserved area, the second quantum dot reserved area and the third quantum dot reserved area using the ultraviolet light of the same wavelength. Of course, the first quantum dot reserved area may be irradiated using the light of H ray to form the first quantum dot unit that emits red light, where the wavelength of the H ray is 405 nm; the second quantum dot reserved area may be irradiated using the light of I ray to form the second quantum dot unit that emits green light, where the wavelength of the I ray is 365 nm; and the third quantum dot reserved area may be irradiated using the light of G ray to form the third quantum dot unit that emits blue light, where the wavelength of the G ray is 436 nm.

Next, data of the residual cadmium element is tested after developing the cadmium-based quantum dots (CdSe) spin-coated on surfaces of different electron transport layers (ZnO). To ensure the reliability of the experimental data, 4 pieces of parallel samples are designed for each group of experiments, as shown in Table 1 below.

TABLE 1

| | Residual amount of cadmium element (ng) | | | |
|---|---|---|---|---|
| Substrate | Piece 1 | Piece 2 | Piece 3 | Piece 4 |
| No azobenzene compound | 657.125 | 425.842 | 748.543 | 243.556 |
| layer is prepared on | | | | |
| surface of ZnO | | | | |
| An azobenzene compound | 0.454 | 0.872 | 0.498 | 1.021 |
| layer of 10 nm is prepared | | | | |
| on surface of ZnO | | | | |

From the data result in Table 1, it can be seen that when an azobenzene compound layer of 10 nm is prepared on the surface of ZnO, during the development process of coated quantum dots, 365 nm UV irradiation is applied to the surface of the substrate to change the configuration of the azobenzene compound and generate an interfacial force. Under the action of the interfacial force, the residual quantum dots are significantly reduced, and reduced by 3 orders of magnitude compared with the residual amount of quantum dots on the ZnO surface not treated with the azobenzene compound.

As shown in FIG. 9, FIG. 9 is an emission spectrogram of a green second quantum dot unit, that is, after the red first quantum dot unit is fabricated, the green second quantum dots are spin-coated and deposited on the substrate surface, and a fluorescence spectrometer is used to detect the emission spectrum of the second quantum dots. It can be seen that there is no emission residual peak of the red first quantum dot unit, indicating that the method for patterning the quantum dot layer provided by an embodiment of the disclosure can effectively solve the problem of residue of the quantum dots in the photolithographic patterning process.

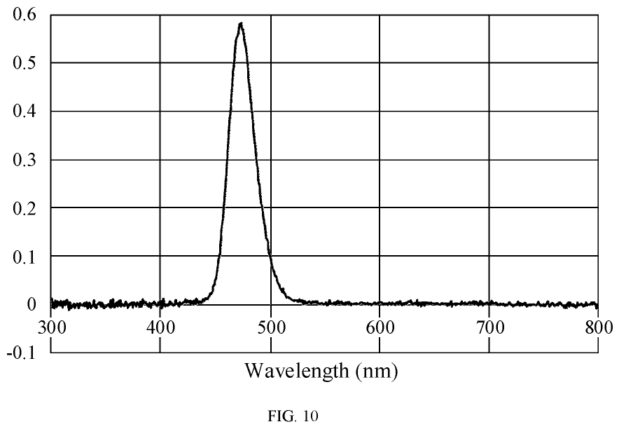

As shown in FIG. 10, FIG. 10 is an emission spectrogram of a blue third quantum dot unit, that is, after the red first quantum dot unit and the green second quantum dot unit are fabricated, the blue third quantum dots are spin-coated and deposited on the substrate surface, and a fluorescence spectrometer is used to detect the emission spectrum of the third quantum dots. It can be seen that there is no emission residual peak of the red first quantum dot unit and the green second quantum dot unit, indicating that the method for patterning the quantum dot layer provided by an embodiment of the disclosure can effectively solve the problem of residue of the quantum dots in the photolithographic patterning process.

In a specific implementation, the color of the light emitted by the first quantum dot unit, the color of the light emitted by the second quantum dot unit, and the color of the light emitted by the third quantum dot unit in an embodiment of the disclosure are red, green, and blue, respectively. In this way, an embodiment of the disclosure completes the patterning process of full-color quantum dots through the above patterning method, and solves the problem of color mixing of quantum dots of different colors, improving the luminous performance of the quantum dot light-emitting device.

Based on the same inventive concept, an embodiment of the disclosure further provides a manufacturing method of a quantum dot light-emitting device, including: forming a quantum dot layer on a substrate by using the method for patterning the quantum dot layer provided in an embodiment of the disclosure.

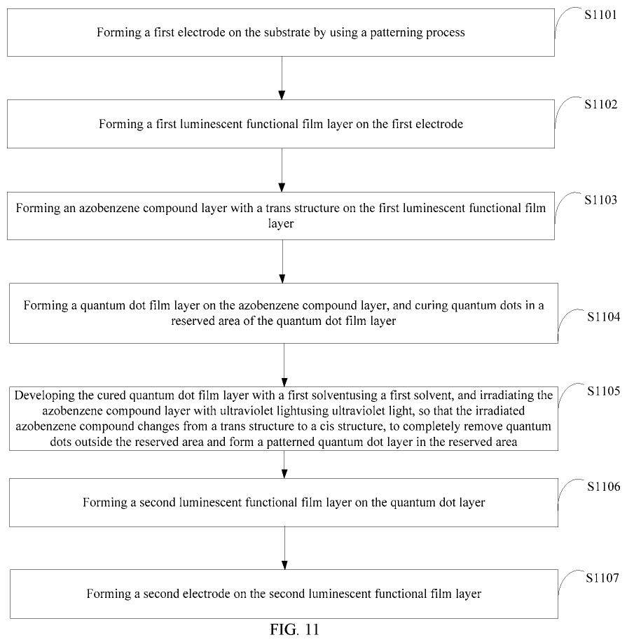

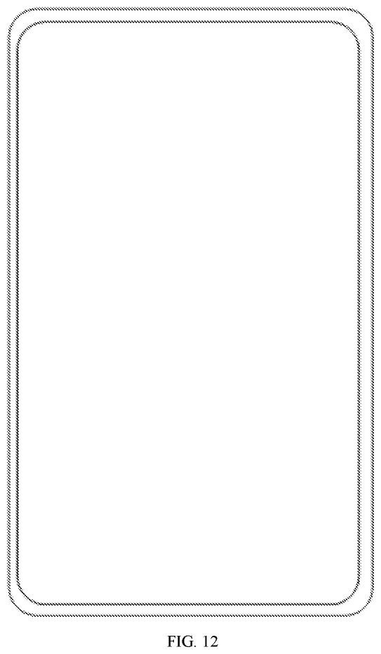

In a specific implementation, forming the quantum dot light-emitting device, as shown in FIG. 11, may include following steps.

S1101: forming a first electrode on the substrate by using a patterning process.

S1102: forming a first luminescent functional film layer on the first electrode.

S1103: forming an azobenzene compound layer with a trans structure on the first luminescent functional film layer.

S1104: forming a quantum dot film layer on the azobenzene compound layer, and curing quantum dots in a reserved area of the quantum dot film layer.

S1105: developing the cured quantum dot film layer using a first solvent, and irradiating the azobenzene compound layer using ultraviolet light, so that irradiated azobenzene compound changes from a trans structure to a cis structure, to completely remove quantum dots outside the reserved area and form a patterned quantum dot layer in the reserved area.

S1106: forming a second luminescent functional film layer on the quantum dot layer.

S1107: forming a second electrode on the second luminescent functional film layer.

In a specific implementation, specific methods of the above-mentioned steps S1101, S1102, S1106 and S1107 provided in embodiments of the disclosure are the same as those in related art, and will not be repeated here. The above-mentioned steps S1103, S1104 and S1105 are similar to the above-mentioned steps S601, S602 and S603, and will not be repeated here.

In a specific implementation, after the second electrode is manufactured, an embodiment of the disclosure further includes an encapsulation process, a cutting process and a bonding process of the quantum dot light-emitting device. These processes are the same as those in related art and will not be described here.

The structure of the quantum dot light-emitting device provided in an embodiment of the disclosure may be a device with an upright structure or a device with an inverted structure.

When the quantum dot light-emitting device is an upright structure, the first electrode is an anode, the second electrode is a cathode, the first luminescent functional layer may include at least one of a hole injection layer, a hole transport layer or an electron blocking layer, and the second luminescent functional layer may include at least one of an electron injection layer, an electron transport layer or a hole blocking layer. Layers of the hole injection layer, the hole transport layer, the electron blocking layer, the electron injection layer, the electron transport layer and the hole blocking layer may be selected and arranged as required. When the quantum dot light-emitting device is an inverted structure, the first electrode is a cathode, the second electrode is an anode, the first luminescent functional layer may include at least one of an electron injection layer, an electron transport layer or a hole blocking layer, and the second luminescent functional layer may include at least one of a hole injection layer, a hole transport layer or an electron blocking layer. Layers of the hole injection layer, the hole transport layer, the electron blocking layer, the electron injection layer, the electron transport layer and the hole blocking layer may be selected and arranged as required.

Based on the same inventive concept, an embodiment of the disclosure further provides a display device, including the above-mentioned quantum dot light-emitting device provided by embodiments of the disclosure. The principle of the display device to solve the problem is similar to that of the above-mentioned quantum dot light-emitting device, so implementations of the display device can refer to implementations of the above-mentioned quantum dot light-emitting device, and the detailed description thereof will be omitted here.

During a specific implementation, the above-mentioned display device according to an embodiment of the disclosure may be an organic light-emitting display device or a liquid crystal display device.

During a specific implementation, the above-mentioned display device according to an embodiment of the disclosure may be a full-screen display device or may be a flexible display device, etc., which is not limited here.

During a specific implementation, the above-mentioned display device according to an embodiment of the disclosure may be a full-screen mobile phone as shown in FIG. 12.

Of course, the above-mentioned display device according to an embodiment of the disclosure may also be a tablet, a television, a display, a laptop, a digital photo frame, a navigator, or any other product or component with display function. All of other indispensable components of the display device should be understood by those ordinary skilled in the art to be included, and will be omitted here and should not be considered as limitations on the disclosure.

During a specific implementation, the display device according to an embodiment of the disclosure may also include other functional film layers well known to those skilled in the art, which will not be described in detail here.

In the quantum dot light-emitting device and the method for patterning the quantum dot layer provided by embodiments of the disclosure, before fabricating the patterned first quantum dot unit, before fabricating the patterned second quantum dot unit and before fabricating the patterned third quantum dot unit, it is necessary to spin-coat a whole quantum dot film layer respectively and then fabricate each quantum dot unit through the photolithography patterning process. In the disclosure, azobenzene compound layers are respectively arranged between the substrate and the first quantum dot unit, between the first quantum dot unit and the second quantum dot unit, and between the second quantum dot unit and the third quantum dot unit, so that one azobenzene compound layer can be deposited before the first quantum dot film layer is spin coated, before the second quantum dot film layer is spin coated and before the third quantum dot film layer is spin coated, and then each quantum dot unit is fabricated through the photolithography patterning process. Since the development process is required for the quantum dot units to be reserved after irradiation during the photolithographic patterning process, the disclosure can irradiate the azobenzene compound layer using the ultraviolet light while developing, or firstly develop the quantum dot units for the first time and then develop the quantum dot units for the second time, and irradiate the azobenzene compound layer using the ultraviolet light while developing for the second time.

Due to the characteristic that the azobenzene compound with a trans structure may undergo the cis-trans isomer conversion under ultraviolet irradiation, that is, the azobenzene compound with the trans structure becomes a cis structure, in the process of the isomer conversion of the azobenzene compound, a molecular-level interfacial force may be generated, to make the quantum dots remaining on the surface of the azobenzene compound layer slide, roll or pull up.

The adhesion between the quantum dots and the surface of the azobenzene compound layer may be reduced to completely remove the quantum dots outside the reserved area, thereby effectively solving the problem of residue of the quantum dot layer in the photolithographic development process, preventing the occurrence of color mixing, and improving the performance of the quantum dot light-emitting device prepared by the photolithographic patterning process.

Evidently those skilled in the art can make various modifications and variations to the disclosure without departing from the spirit and scope of the disclosure. Thus the disclosure is also intended to encompass these modifications and variations to the disclosure as long as these modifications and variations come into the scope of the claims of the disclosure and their equivalents.

1. A quantum dot light-emitting device, comprising:
a substrate;
a quantum dot layer located on the substrate; wherein the quantum dot layer comprises a first quantum dot unit, a second quantum dot unit and a third quantum dot unit that emit light of different colors, orthographic projections of the first quantum dot unit, the second quantum dot unit and the third quantum dot unit on the substrate do not overlap with each other, a distance between a bottom surface of the first quantum dot unit and a surface of the substrate, a distance between a bottom surface of the second quantum dot unit and the surface of the substrate, and a distance between a bottom surface of the third quantum dot unit and the surface of the substrate increase sequentially; wherein:
an azobenzene compound layer is arranged between the substrate and the first quantum dot unit, between the first quantum dot unit and the second quantum dot unit, and between the second quantum dot unit and the third quantum dot unit, an orthographic projection of the azobenzene compound layer on the substrate completely covers the substrate, and an azobenzene compound of the azobenzene compound layer has a trans structure.

2. The quantum dot light-emitting device according to claim 1, wherein a thickness of each azobenzene compound layer is in a range of 1 nm to 10 nm.

3. The quantum dot light-emitting device according to claim 1, wherein a surface of the third quantum dot unit is flush with a surface of the azobenzene compound layer farthest from the substrate.

4. The quantum dot light-emitting device according to claim 1, wherein the quantum dot layer is a film layer after ligands on surfaces of quantum dots are cross-linked.

5. The quantum dot light-emitting device according to claim 1, wherein the azobenzene compound layer between the substrate and the first quantum dot unit is a first azobenzene compound layer, and the quantum dot light-emitting device further comprises: a first electrode located between the substrate and the first azobenzene compound layer, a first luminescent functional layer located between the first electrode and the first azobenzene compound layer, a second luminescent functional layer located on a side of the quantum dot layer away from the substrate, and a second electrode located on a side of the second luminescent functional layer away from the substrate.

6. The quantum dot light-emitting device according to claim 5, wherein the first electrode is an anode, the second electrode is a cathode, the first luminescent functional layer comprises at least one of a hole injection layer, a hole transport layer or an electron blocking layer, and the second luminescent functional layer comprises at least one of an electron injection layer, an electron transport layer or a hole blocking layer.

7. The quantum dot light-emitting device according to claim 5, wherein the first electrode is a cathode, the second electrode is an anode, the first luminescent functional layer comprises at least one of an electron injection layer, an electron transport layer or a hole blocking layer, and the second luminescent functional layer comprises at least one of a hole injection layer, a hole transport layer or an electron blocking layer.

8. The quantum dot light-emitting device according to claim 6, wherein when the electron transport layer is comprised, a material of the electron transport layer comprises at least one of zinc oxide, magnesium zinc oxide, aluminum zinc oxide, tin oxide or titanium oxide;
wherein when the hole transport layer is comprised, a material of the hole transport layer comprises at least one of CBP, NPB, TPD, nickel oxide, tungsten oxide, molybdenum oxide, cuprous oxide or vanadium oxide.

9. (canceled)

10. The quantum dot light-emitting device according to claim 1, wherein a material of the substrate is glass, polyimide or silicon wafer, and the azobenzene compound layer closest to the substrate is in direct contact with the substrate.

11. A display device, comprising a quantum dot light-emitting device, the quantum dot light-emitting device comprising:
a substrate;
a quantum dot layer located on the substrate; wherein the quantum dot layer comprises a first quantum dot unit, a second quantum dot unit and a third quantum dot unit that emit light of different colors, orthographic projections of the first quantum dot unit, the second quantum dot unit and the third quantum dot unit on the substrate do not overlap with each other, a distance between a bottom surface of the first quantum dot unit and a surface of the substrate, a distance between a bottom surface of the second quantum dot unit and the surface of the substrate, and a distance between a bottom surface of the third quantum dot unit and the surface of the substrate increase sequentially; wherein:
an azobenzene compound layer is arranged between the substrate and the first quantum dot unit, between the first quantum dot unit and the second quantum dot unit, and between the second quantum dot unit and the third quantum dot unit, an orthographic projection of the azobenzene compound layer on the substrate completely covers the substrate, and an azobenzene compound of the azobenzene compound layer has a trans structure.

12. A method for patterning a quantum dot layer, comprising:
forming an azobenzene compound layer with a trans structure on a substrate;
forming a quantum dot film layer on the azobenzene compound layer, and curing quantum dots in a reserved area of the quantum dot film layer;
developing the cured quantum dot film layer using a first solvent, and irradiating the azobenzene compound layer using ultraviolet light, so that irradiated azobenzene compound changes from a trans structure to a cis structure, to completely remove quantum dots outside the reserved area and form a patterned quantum dot layer in the reserved area.

13. The method for patterning the quantum dot layer according to claim 12, wherein developing the cured quantum dot film layer using the first solvent, and irradiating the azobenzene compound layer using the ultraviolet light, comprises:
developing the cured quantum dot film layer for a first time using the first solvent, to remove the quantum dots outside the reserved area;
developing the cured quantum dot film layer for a second time using the first solvent, and simultaneously irradiating the azobenzene compound layer using the ultraviolet light.

14. The method for patterning the quantum dot layer according to claim 12, wherein developing the cured quantum dot film layer using the first solvent, and irradiating the azobenzene compound layer using the ultraviolet light, comprises:
developing the cured quantum dot film layer using the first solvent, and simultaneously irradiating the azobenzene compound layer using the ultraviolet light.

15. The method for patterning the quantum dot layer according to claim 12, wherein forming the quantum dot film layer on the azobenzene compound layer, and curing the quantum dots in the reserved area of the quantum dot film layer, comprises:
forming a quantum dot film layer with cross-linkable ligands on the azobenzene compound layer;
irradiating the quantum dots in the reserved area using light of a predetermined wavelength, so that ligands on surfaces of the quantum dots in the reserved area are cross-linked to cure the quantum dots in the reserved area;
wherein the cross-linkable ligands comprise at least one of 2-propene-1-thiol, isopentenyl thiol, N,N-methylene bisacrylamide, 1,6-hexanediol diacrylate, or diallyl sulfide.

16. (canceled)

17. The method for patterning the quantum dot layer according to claim 12, wherein forming the quantum dot film layer on the azobenzene compound layer, and curing the quantum dots in the reserved area of the quantum dot film layer, comprises:
forming a quantum dot film layer with a photosensitive material and with ligands on a surface thereof on the azobenzene compound layer;
irradiating the quantum dots in the reserved area using light of a predetermined wavelength; wherein the photosensitive material or a product of the photosensitive material after irradiation of the light reacts with ligands on surfaces of the quantum dots under irradiation of the light of the preset wavelength, to make the ligands fall off from the surfaces of the quantum dots to change solubility of the quantum dots in the reserved area, and make the quantum dots in the reserved area coagulate to cure the quantum dots in the reserved area.

18. The method for patterning the quantum dot layer according to claim 17, wherein the ligands on the surfaces of the quantum dots comprise at least one of oleic acid, oleylamine, trioctylphosphine, or dodecanethiol;
wherein the photosensitive material comprises a photoacid generator, an olefin-like substance or an alkyne-like substance.

19. (canceled)

20. The method for patterning the quantum dot layer according to claim 12, wherein forming the azobenzene compound layer with the trans structure on the substrate, comprises:
forming the azobenzene compound layer on the substrate through spin coating, spray coating, blade coating or vapor deposition.

21. The method for patterning the quantum dot layer according to claim 12, wherein irradiating the azobenzene compound layer using the ultraviolet light, comprises:
irradiating the azobenzene compound layer from a side of the quantum dot film layer using the ultraviolet light.

22. A manufacturing method of a quantum dot light-emitting device,
comprising: forming a quantum dot layer on a substrate by using the method for patterning the quantum dot layer according to claim 12.

23. The manufacturing method according to claim 22, wherein forming the quantum dot light-emitting device, comprises:
forming a first electrode on the substrate by using a patterning process;
forming a first luminescent functional film layer on the first electrode;
forming an azobenzene compound layer with a trans structure on the first luminescent functional film layer;
forming a quantum dot film layer on the azobenzene compound layer, and curing quantum dots in a reserved area of the quantum dot film layer;
developing the cured quantum dot film layer using a first solvent, and irradiating the azobenzene compound layer using ultraviolet light, so that irradiated azobenzene compound changes from a trans structure to a cis structure, to completely remove quantum dots outside the reserved area and form a patterned quantum dot layer in the reserved area;
forming a second luminescent functional film layer on the quantum dot layer;
forming a second electrode on the second luminescent functional film layer.
